(19) United States
(12) Patent Application Publication
(10) Pub. No.: US 2007/0272942 A1
(43) Pub. Date: Nov. 29, 2007

(54) SEMICONDUCTOR DEVICE AND METHOD OF MANUFACTURING THE SAME

(75) Inventor: Seiji Otake, Saitama (JP)

Correspondence Address: FISH & RICHARDSON P.C., P.O. BOX 1022, MINNEAPOLIS, MN, 55440-1022, US

(73) Assignee: SANYO ELECTRIC CO., LTD., Osaka (JP)

(21) Appl. No.: 11/751,162

(22) Filed: May 21, 2007

(30) Foreign Application Priority Data
May 25, 2006 (JP) 2006-145601

(51) Int. Cl. H01L 29/74

(52) U.S. Cl. 257/139

(57) ABSTRACT

In a semiconductor device of the present invention, an N type epitaxial layer is divided into a plurality of element formation regions by an isolation region. In one of the element formation regions, a resistance is formed. Around the resistance, a protection element having a PN junction region is formed. The PN junction region has a junction breakdown voltage lower than that of a PN junction region of the resistance. By use of this structure, when negative ESD surge is applied to a pad for an electrode which applies a voltage to a P type diffusion layer, the PN junction region of the protection element breaks down. Accordingly, the resistance can be protected.

### BACKGROUND OF THE INVENTION

Priority is claimed to Japanese Patent Application Number JP2006-145601 filed on May 25, 2006, the disclosure of which is incorporated herein by reference in its entirety.

1. Field of the Invention

The present invention relates to a semiconductor device in which ESD (Electro-Static Discharge) resistance is improved, and a method of manufacturing the same.

2. Description of the Related Art

As an example of conventional semiconductor devices, the following device using surge protection elements has been known. For example, a total of four surge protection elements are disposed respectively near four sides of a rectangular or substantially rectangular pad, one on each side. The pad is connected with one of electrodes of each of the surge protection elements by wiring. A wire for distributing a surge current is connected with the other one of the electrodes of each of the surge protection elements by wiring. Note that a potential of the pad is supplied to an internal circuit through the wiring. Moreover, each of the surge protection elements is, for example, a Zener diode, a PMOS diode or an NMOS diode. By use of this structure, the surge current applied to the pad is dispersed to all of the surge protection elements disposed around the pad. Accordingly, a surge breakdown resistance of a semiconductor device is improved. This technique is described for instance in Japanese Patent Application Publication No. 2002-313947.

As another example of conventional semiconductor devices, the following insulated gate bipolar transistor including surge protection elements has been known. For example, an N type epitaxial layer used as a drift layer is formed on a P type semiconductor substrate used as a collector layer. In an N type epitaxial layer used as an internal cell part, P type diffusion layers used as channel regions are formed. Moreover, in each of the P type diffusion layers, N type diffusion layers used as emitter regions are formed. Furthermore, in an N type epitaxial layer used as an electrode pad or a field plate part, the P type diffusion layer having the same shape as that of the P type diffusion layer used as the channel region is formed. By use of this structure, when ESD surge is applied to a collector electrode, avalanche breakdown occurs evenly in the entirety of a chip. Accordingly, current concentration in a certain region is prevented. As a result, surge resistance of the entirety of the chip to ESD is improved. This technique is described for instance in Japanese Patent Application Publication No. 2003-188381.

As described above, a structure for the conventional semiconductor device has been known, in which a plurality of surge protection elements are disposed around a pad, and in which a surge current applied to the pad is dispersed to all of the surge protection elements. By using this structure, the surge current is prevented from flowing into an internal circuit, and is thereby prevented from breaking down the internal circuit. However, the following problem may occur depending on the magnitude of the surge current and the like. Specifically, a problem of breakdown of an internal circuit may occur, when the surge current is too large, for example. This is because the surge protection elements around the pad cannot cope with such a large surge current into the internal circuit.

Moreover, as described above, a structure for the conventional semiconductor device has been known, in which avalanche breakdown occurs evenly in the entirety of a chip when ESD surge is applied to the collector electrode. In this structure, the avalanche breakdown also occurs in an internal cell when the ESD surge is applied. Accordingly, depending on the magnitude of the applied ESD surge, a problem may occur that the internal cell is broken down.

### SUMMARY OF THE INVENTION

The present invention was made in consideration of the foregoing circumstances. A semiconductor device of the present invention includes a semiconductor layer, a diffusion layer used as the resistance formed in the semiconductor layer, a first junction region between the diffusion layer used as the resistance and the semiconductor layer and a protection element. The protection element is disposed around the diffusion layer used as the resistance, and has a second junction region having a junction breakdown voltage lower than that of the first junction region. Accordingly, in the present invention, the second junction region of the protection element breaks down before the first junction region of the resistance. By use of this structure, the resistance can be protected from an overvoltage.

Moreover, the semiconductor device of the present invention further includes an isolation region which divides the semiconductor layer. The diffusion layer used as the resistance is formed in one of regions divided by the isolation region. Moreover, the protection element is formed by utilizing the isolation region surrounding the diffusion layer used as the resistance. Accordingly, in the present invention, the protection element is formed by utilizing the isolation region. By use of this structure, a current generated by the overvoltage is caused to flow into a substrate through the isolation region, and then dispersed.

Moreover, in the semiconductor device of the present invention, the semiconductor layer is formed by stacking a semiconductor substrate of one conductivity type with at least one epitaxial layer of opposite conductivity type. The second junction region is formed of a first diffusion layer of the one conductivity type and a diffusion layer of the opposite conductivity type. To the first diffusion layer of the one conductivity type, a low potential applied to the diffusion layer used as the resistance is applied. The diffusion layer of the opposite conductivity type is formed in the epitaxial layer. The diffusion layer of the opposite conductivity type is disposed so as to overlap a second diffusion layer of the one conductivity type connected to the semiconductor substrate. Accordingly, in the present invention, the current generated by the overvoltage is dispersed after flowing into the substrate through the diffusion layer of the one conductivity type connected to the substrate.

Moreover, the semiconductor device of the present invention further includes an isolation region which divides the epitaxial layer. The second diffusion layer of the one conductivity type is a diffusion layer included in the isolation regions. Accordingly, in the present invention, the current generated by the overvoltage is dispersed into the substrate through the isolation region. Moreover, by utilizing the isolation region, a dedicated protection element can be formed for each semiconductor element.

Moreover, in the semiconductor device of the present invention, the first diffusion layer of the one conductivity type and the diffusion layer of the opposite conductivity type are circularly disposed around the formation region of the diffusion layer used as the resistance, and along a formation region of the isolation region. Accordingly, in the present invention, by utilizing the isolation region, it is possible to prevent concentration of the current, which is generated by the overvoltage, in the protection element.

Moreover, in the semiconductor device of the present invention, the protection element operates as a bipolar transistor. Accordingly, in the present invention, by operating the protection element used as the bipolar transistor, current capacity in the protection element can be improved.

Moreover, a semiconductor device of the present invention includes a semiconductor layer, a diode formed in the semiconductor layer, a first junction region between the semiconductor layer and a diffusion layer included in the diode and a protection element. The protection element is disposed around a formation region of the diode, and has a second junction region having a junction breakdown voltage lower than that of the first junction region. Accordingly, in the present invention, the second junction region of the protection element breaks down before the first junction region of the diode. This structure can protect the diode from an overvoltage.

A method of manufacturing a semiconductor device according to the present invention is a method of manufacturing a semiconductor device in which at least one epitaxial layer of opposite conductivity type is formed on a semiconductor substrate of one conductivity type, in which an isolation region dividing the epitaxial layer into a plurality of element formation regions is formed, and in which a diffusion layer used as a resistance is formed in one of the plurality of element formation regions. The method includes the steps of forming a first diffusion layer of the one conductivity type around the diffusion layer used as the resistance; forming a diffusion layer of the opposite conductivity type which partially overlaps with the first diffusion layer of the one conductivity type and a second diffusion layer of the one conductivity type included in the isolation region and connecting the diffusion layer used as the resistance to the first diffusion layer of the one conductivity type by use of a wiring layer on the epitaxial layer. Accordingly, in the present invention, by forming a protection element around the diffusion layer used as the resistance, the resistance can be protected from an overvoltage.

Moreover, in the method of manufacturing a semiconductor device according to the present invention, the diffusion layer used as the resistance and the first diffusion layer of the one conductivity type are formed in the same process. Accordingly, in the present invention, by forming the diffusion layer used as the resistance and the diffusion layer for the protection element in the same step, manufacturing costs can be reduced.

Moreover, a method of manufacturing a semiconductor device according to the present invention is a method of manufacturing a semiconductor device in which, on a semiconductor substrate of one conductivity type, at least one epitaxial layer of opposite conductivity type is formed, in which an isolation region dividing the epitaxial layer into a plurality of element formation regions is formed, and in which a diode is formed in one of the plurality of element formation regions. The method includes the steps of forming a first diffusion layer of the one conductivity type around a formation region of the diode forming a diffusion layer of the opposite conductivity type which partially overlaps the first diffusion layer of the one conductivity type and a second diffusion layer of the one conductivity type included in the isolation region and connecting a diffusion layer used as an anode region of the diode to the first diffusion layer of the one conductivity type by use of a wiring layer on the epitaxial layer. Therefore, in the present invention, by forming a protection element around the diode, the diode can be protected from an overvoltage.

### BRIEF DESCRIPTION OF THE DRAWINGS

FIG. 1 is a cross-sectional view showing a semiconductor device according to a first embodiment of a present invention.

FIG. 2 is a graph showing characteristics of a protection element in the semiconductor device according to the first embodiment of the present invention.

FIG. 3 is a cross-sectional view showing a semiconductor device according to a second embodiment of the present invention.

FIG. 4 is a first cross-sectional view showing a method of manufacturing a semiconductor device according to the first embodiment of the present invention.

FIG. 5 is a second cross-sectional view showing the method of manufacturing a semiconductor device according to the first embodiment of the present invention.

FIG. 6 is a third cross-sectional view showing the method of manufacturing a semiconductor device according to the first embodiment of the present invention.

FIG. 7 is a fourth cross-sectional view showing the method of manufacturing a semiconductor device according to the first embodiment of the present invention.

FIG. 8 is a fifth cross-sectional view showing the method of manufacturing a semiconductor device according to the first embodiment of the present invention.

FIG. 9 is a sixth cross-sectional view showing the method of manufacturing a semiconductor device according to the first embodiment of the present invention.

FIG. 10 is a seventh cross-sectional view showing the method of manufacturing a semiconductor device according to the first embodiment of the present invention.

FIG. 11 is a firth cross-sectional view showing the method of manufacturing a semiconductor device according to the second embodiment of the present invention.

FIG. 12 is a second cross-sectional view showing the method of manufacturing a semiconductor device according to the second embodiment of the present invention.

FIG. 13 is a third cross-sectional view showing the method of manufacturing a semiconductor device according to the second embodiment of the present invention.

FIG. 14 is a fourth cross-sectional view showing the method of manufacturing a semiconductor device according to the second embodiment of the present invention.

FIG. 15 is a fifth cross-sectional view showing the method of manufacturing a semiconductor device according to the second embodiment of the present invention.

FIG. 16 is a sixth cross-sectional view showing the method of manufacturing a semiconductor device according to the second embodiment of the present invention.

FIG. 17 is a seventh cross-sectional view showing the method of manufacturing a semiconductor device according to the second embodiment of the present invention.

### DETAILED DESCRIPTION OF THE PREFERRED EMBODIMENTS

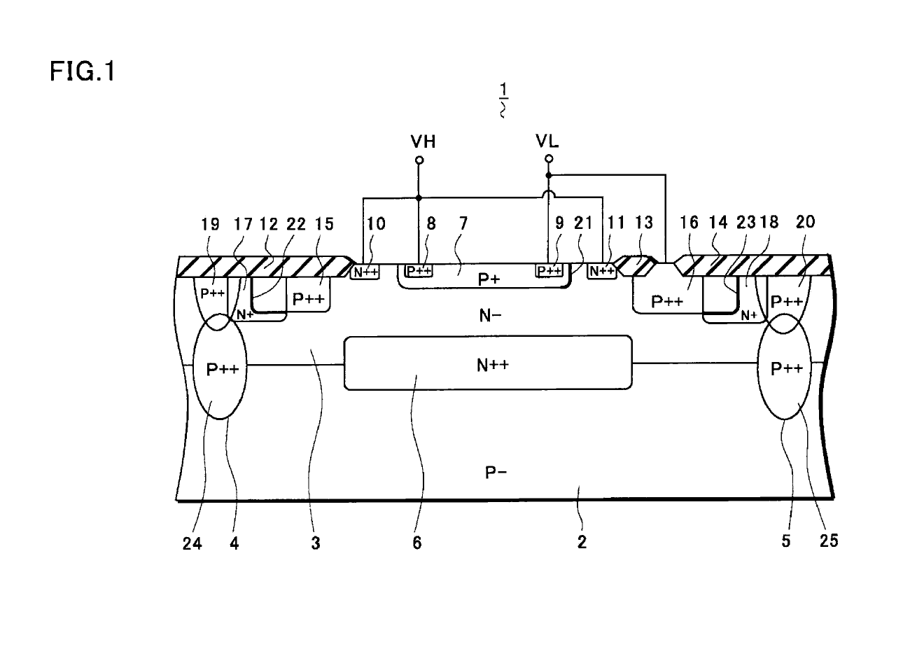

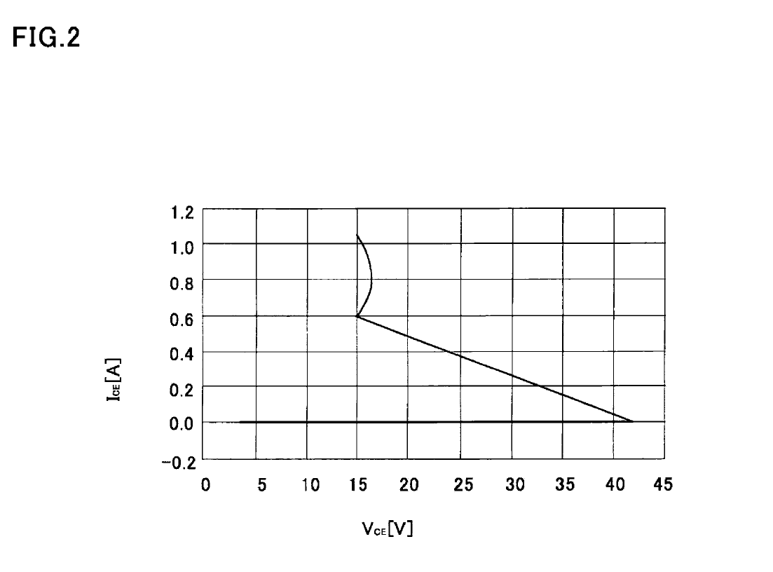

With reference to FIGS. 1 and 2, a semiconductor device according to a first embodiment of a present invention will be described in detail below. FIG. 1 is a cross-sectional view for explaining the semiconductor device according to this embodiment. FIG. 2 is a graph for explaining characteristics of a protection element in this embodiment.

As shown in FIG. 1, a resistance 1 mainly includes a P type single crystal silicon substrate 2, an N type epitaxial layer 3, isolation regions 4 and 5, an N type buried diffusion layer 6 and P type diffusion layers 7 to 9 used as resistances.

The N type epitaxial layer 3 is formed on the P type single crystal silicon substrate 2. Note that, although one epitaxial layer 3 is formed on the substrate 2 in this embodiment, the embodiment of the present invention is not limited to this case. For example, a plurality of epitaxial layers may be laminated on the substrate.

The isolation regions 4 and 5 are formed in the substrate 2 and the epitaxial layer 3. The epitaxial layer 3 is divided into a plurality of element formation regions by the isolation regions 4 and 5. For example, the isolation regions 4 and 5 are circularly formed so as to surround a formation region of the resistance 1.

The N type buried diffusion layer 6 is formed so as to extend in both regions of the substrate 2 and the epitaxial layer 3. As shown in FIG. 1, the N type buried diffusion layer 6 is formed across the formation region of the resistance 1 defined by the isolation regions 4 and 5.

The P type diffusion layers 7 to 9 are formed in the epitaxial layer 3. The P type diffusion layers 7 to 9 are used as a diffusion resistance. The P type diffusion layers 8 and 9 are used as lead-out diffusion layers connected to an electrode which applies a voltage to the P type diffusion layer 7. Moreover, a high potential, for example, a power supply potential is applied to the P type diffusion layer 8, and a low potential, for example, a ground potential is applied to the P type diffusion layer 9. Note that the P type diffusion layers 8 and 9 are disposed so as to face each other within a formation region of the P type diffusion layer 7.

N type diffusion layers 10 and 11 are formed in the epitaxial layer 3. As shown in FIG. 1, the N type diffusion layers 10 and 11 are wired so as to have the same potential as that applied to the P type diffusion layer 8 used as the resistance 1. By use of this structure, the N type epitaxial layer 3 and the P type diffusion layer 7 are set to have substantially the same potential. Moreover, a PN junction region between the N type epitaxial layer 3 and the P type diffusion layer 7 is not operated. Note that the N type diffusion layers 10 and I1 may be circularly disposed around the P type diffusion layer 7.

LOCOS (Local Oxidation of Silicon) oxide films 12 to 14 are formed in the epitaxial layer 3. Each of the LOCOS oxide films 12 to 14 has a thickness of, for example, about 3000 to 10000 Å in its flat portion.

P type diffusion layers 15 and 16 are formed in the epitaxial layer 3. The P type diffusion layers 15 and 16 are disposed around the formation region of the resistance 1 in the region defined by the isolation regions 4 and 5. Moreover, as shown in FIG. 1, the P type diffusion layers 15 and 16 are wired so as to have the same potential as that applied to the P type diffusion layer 9 used as the resistance 1. Note that the P type diffusion layers 15 and 16 may be circularly disposed around the formation region of the resistance 1 so as to correspond to arrangement of the isolation regions 4 and 5.

N type diffusion layers 17 and 18 are formed in the epitaxial layer 3. The N type diffusion layers 17 and 18 are formed so as to at least partially overlap the P type diffusion layers 15 and 16, respectively. Furthermore, the N type diffusion layers 17 and 18 are formed so as to at least partially overlap P type diffusion layers 19 and 20 included in the isolation regions 4 and 5, respectively. The N type diffusion layers 17 and 18 are not connected directly to a wiring layer (not shown) on the epitaxial layer 3. However, substantially the same potential as that applied to the P type diffusion layer 8 used as the resistance 1 is applied to the N type diffusion layers 17 and 18 through the epitaxial layer 3. Note that the N type diffusion layers 17 and 18 may be circularly disposed around the formation region of the resistance 1 so as to correspond to the arrangement of the isolation regions 4 and 5.

Next, as indicated by a thick solid line, a PN junction region 21 is formed between the N type epitaxial layer 3 and the P type diffusion layer 7 positioned near the P type diffusion layer 9 of the resistance 1. As described above, substantially the same potential as that applied to the P type diffusion layer 9 is applied to the P type diffusion layer 7 positioned near the P type diffusion layer 9. Meanwhile, substantially the same potential as that applied to the P type diffusion layer 8 is applied to the N type epitaxial layer 3 through the N type diffusion layer 11. That is, a reverse bias is applied to the PN junction region 21 of the resistance 1.

Moreover, as indicated by thick solid lines, a PN junction region 22 is formed between the P type diffusion layer 15 and the N type diffusion layer 17, and a PN junction region 23 is formed between the P type diffusion layer 16 and the N type diffusion layer 18. The PN junction regions 22 and 23 are also formed around the formation region of the resistance 1. As described above, substantially the same potential as that applied to the P type diffusion layer 8 is applied to the P type diffusion layers 15 and 16 through the wiring layer on the epitaxial layer 3. Meanwhile, substantially the same potential as that applied to the P type diffusion layer 8 is applied to the N type diffusion layers 17 and 18 through the epitaxial layer 3. That is, substantially the same reverse bias as that applied to the PN junction region 21 is applied to the PN junction regions 22 and 23.

Here, the PN junction regions 22 and 23 are formed so as to have a junction breakdown voltage lower than that of the PN junction region 21. For example, as shown in FIG. 1, there is a structure in which the P type diffusion layer 7 is formed in a process different from one in which the P type diffusion layers 15 and 16 are formed. In addition, the P type diffusion layer 7 is formed so as to have an impurity concentration lower than that of the P type diffusion layers 15 and 16. Furthermore, the N type diffusion layers 17 and 18 are formed in the N type epitaxial layer 3. That is, in each of the PN junction regions 22 and 23, impurity concentrations of its P type and N type regions are increased compared with the PN junction region 21. Moreover, the junction breakdown voltage of the PN junction regions 22 and 23 is controlled so as to have a desired characteristic value.

Moreover, although not shown in FIG. 1, there is a structure in which the P type diffusion layers 7, 15 and 16 are formed in the same process so as to have the same impurity concentration. In this case, formation of the N type diffusion layers 17 and 18 in the N type epitaxial layer 3 increases the impurity concentration on the N type region side in each of the PN junction regions 22 and 23 compared with the PN junction region 21. That is, by controlling the impurity concentration of the N type diffusion layers 17 and 18, the junction breakdown voltage of the PN junction regions 22 and 23 is controlled so as to have the desired characteristic value.

By use of the structure described above, for example, when an overvoltage, for example, negative ESD surge is applied to a pad for an electrode applying voltage to the P type diffusion layer 9 of the resistance 1, the PN junction regions 22 and 23 break down before the PN junction region 21 breaks down. A breakdown current then flows through the PN junction regions 22 and 23 to prevent breakdown of the PN junction region 21. Accordingly, the resistance 1 can be protected from the ESD surge. Specifically, protection elements having the PN junction regions 22 and 23 are operated against the ESD surge. As a result, the resistance 1 can be protected.

Furthermore, in the protection elements having the PN junction regions 22 and 23, the PN junction regions 22 and 23 are formed across a wide region by disposing the P type diffusion layers 15 and 16 and the N type diffusion layers 17 and 18, and along the arrangement of the isolation regions 4 and 5. This structure makes it possible to prevent concentration of the breakdown current in the PN junction regions 22 and 23. Accordingly, it is possible to suppress breakdown of the protection elements having the PN junction regions 22 and 23.

Furthermore, the protection elements having the PN junction regions 22 and 23 are formed by utilizing the isolation regions 4 and 5 within the element formation region defined by the isolation regions 4 and 5. By use of this structure, the junction breakdown voltage of the protection element can be determined according to each of semiconductor elements formed in the element formation region defined by the isolation regions. That is, protection elements suitable for the respective semiconductor elements can be individually disposed, and thus each of the semiconductor elements can be protected from the ESD surge and the like. For example, even when an ESD surge protection element is disposed around the pad for an electrode applying voltage to the P type diffusion layer 9, the semiconductor elements can be more surely protected by further forming the protection elements described above in the formation regions of the respective semiconductor elements. In addition, an actual operation region of a chip can be effectively utilized by using the isolation regions to include the protection elements in each of the element formation regions.

In FIG. 2, a horizontal axis shows a collector-emitter voltage (V_{CE}) of a PNP transistor, and a vertical axis shows a collector-emitter current (I_{CE}) of the PNP transistor. Note that FIG. 2 shows data on the PNP transistor in which the P type diffusion layers 15 and 16 (see FIG. 1) are set to be emitter regions, the N type diffusion layers 17 and 18 (see FIG. 1) are set to be base regions, and the P type diffusion layers 19, 20, 24 and 25 (see FIG. 1) are set to be collector regions.

As described above, the N type diffusion layers 17 and 18 having the PN junction regions 22 and 23 formed respectively therein are formed so as to also overlap the P type diffusion layers 19 and 20. The P type diffusion layers 19, 20, 24 and 25 are electrically connected to the substrate 2 in order to form the isolation regions 4 and 5. By use of this structure, the protection elements having the PN junction regions 22 and 23 operate as the PNP transistors including the P type diffusion layers 15 and 16, the N type diffusion layers 17 and 18, and the P type diffusion layers 19, 20, 24 and 25.

For example, suppose a case where negative ESD surge is applied to the pad for the source electrode in the resistance 1. When the PN junction regions 22 and 23 break down, a current flows between the base and the emitter of the PNP transistor, and the PNP transistor is turned on. When the PNP transistor is turned on, a breakdown current flows into the substrate 2. That is, when each of the protection elements having the PN junction regions 22 and 23 operates as a bipolar transistor, the breakdown current flows into the substrate 2 and disperses therein.

In this event, as shown in FIG. 2, a reverse bias is applied between the collector and the emitter of the PNP transistor, and the PNP transistor is turned on when V_{CE} becomes 42 (V), for example. Moreover, when the PNP transistor is turned on, the conductivity modulation is caused at the P type diffusion layers 19, 20, 24 and 25 used as the collector regions. Accordingly, a resistance value is significantly reduced, and current capacity is improved. Specifically, when each of the protection elements having the PN junction regions 22 and 23 operates as the bipolar transistor, capacity of the breakdown current flowing into the substrate 2 is improved.

Moreover, as shown in FIG. 1, when the breakdown current flows through the isolation regions 4 and 5, potentials of the substrate 2 and the isolation regions 4 and 5 are changed. However, by operating the protection element as the bipolar transistor, a range of potential changes in the substrate 2 and the isolation regions 4 and 5 can be decreased. Moreover, the potential change in the substrate 2 can prevent malfunction of semiconductor elements formed in other element formation regions.

Meanwhile, for example, when positive ESD surge is applied to the pad for the source electrode in the resistance 1, a forward bias is applied to the PN junction region 21 and the PN junction regions 22 and 23. In this case, as described above, the PN junction regions 22 and 23 become low resistance regions by the N type diffusion layers 17 and 18. Moreover, by disposing the P type diffusion layers 15 and 16 and the N type diffusion layers 17 and 18 in wide regions, and along the isolation regions 4 and 5, a current path width is increased. Accordingly, the PN junction regions 22 and 23 become much lower resistance regions. By use of this structure, a current generated by application of the positive ESD surge flows into the substrate 2 mainly through the PN junction regions 22 and 23. Also in this event, when each of the protection elements having the PN junction regions 22 and 23 operates as the bipolar transistor, capacity of the current flowing into the substrate 2 is improved. Moreover, the resistance 1 is protected by preventing breakdown of the PN junction regions 22 and 23 due to concentration of the current generated by application of the positive ESD surge.

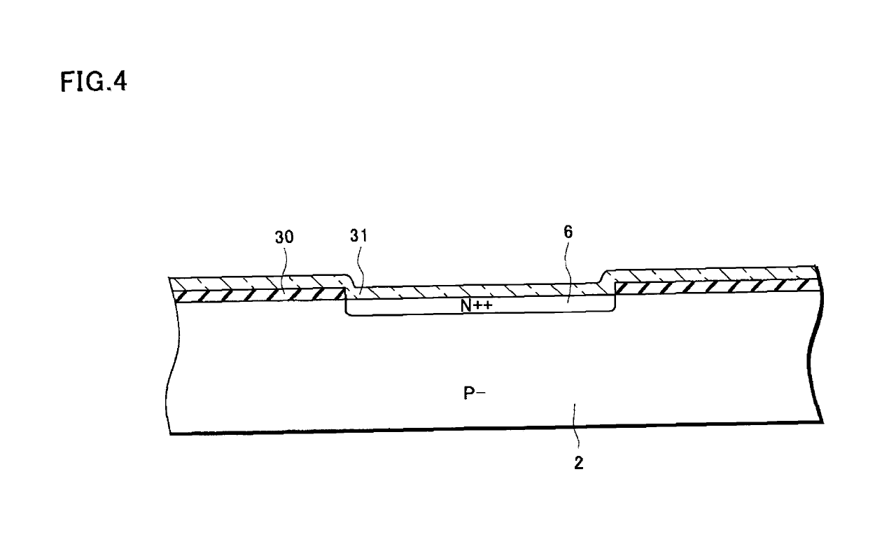

Next, with reference to FIGS. 4 to 10, detailed description will be given of a method of manufacturing a semiconductor device according to a first embodiment of the present invention. FIGS. 4 to 10 are cross-sectional views showing the method of manufacturing a semiconductor device according to this embodiment. Note that FIGS. 4 to 10 show a method of manufacturing the semiconductor device shown in FIG. 1.

First, as shown in FIG. 4, a P type single crystal silicon substrate 2 is prepared. A silicon oxide film 30 is formed on the substrate 2, and the silicon oxide film 30 is selectively removed so as to form an opening in a formation region of an N type buried diffusion layer 6. Thereafter, by using the silicon oxide film 30 as a mask, a liquid source 31 containing an N type impurity, for example, antimony (Sb) is applied onto a surface of the substrate 2 by use of a spin-coating method. Subsequently, after antimony (Sb) is thermally diffused to form the N type buried diffusion layer 6, the silicon oxide film 30 and the liquid source 31 are removed.

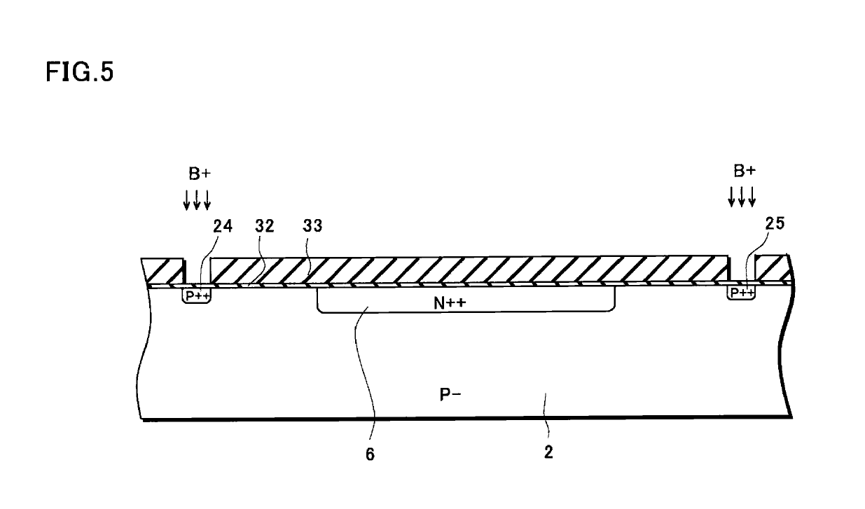

Next, as shown in FIG. 5, a silicon oxide film 32 is formed on the substrate 2 and a photoresist 33 is formed on the silicon oxide film 32. Thereafter, by use of a heretofore known photolithography technique, openings are formed in the photoresist 33 on regions where P type buried diffusion layers 24 and 25 are to be respectively formed. Subsequently, ions of a P type impurity, for example, boron (B) are implanted from the surface of the substrate 2 at an accelerating voltage of 40 to 180 (keV) and a dose of 1.0×10¹³ to 1.0×10¹⁶ (/cm²). After the photoresist 33 is removed and the P type buried diffusion layers 24 and 25 are formed by thermal diffusion, the silicon oxide film 32 is removed.

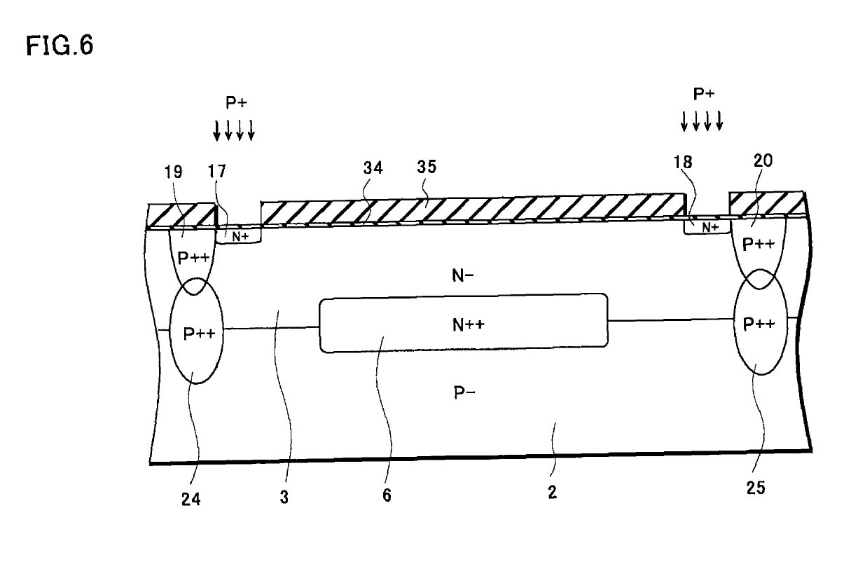

Next, as shown in FIG. 6, the substrate 2 is placed on a susceptor of a vapor phase epitaxial growth apparatus, and an N type epitaxial layer 3 is formed on the substrate 2. The vapor phase epitaxial growth apparatus mainly includes a gas supply system, a reactor, an exhaust system and a control system. In this embodiment, by use of a vertical reactor, thickness uniformity of the epitaxial layer can be improved. The N type buried diffusion layer 6 and the P type buried diffusion layers 24 and 25 are thermally diffused by heat treatment in the step of forming the epitaxial layer 3.

Next, by use of the heretofore known photolithography technique, P type diffusion layers 19 and 20 are formed in the epitaxial layer 3. Thereafter, a silicon oxide film 34 is formed on the epitaxial layer 3, and a photoresist 35 is formed on the silicon oxide film 34. Subsequently, by use of the heretofore known photolithography technique, openings are formed in the photoresist 35 on regions where N type diffusion layers 17 and 18 are to be respectively formed. Thereafter, ions of an N type impurity, for example, phosphorus (P) are implanted from the surface of the epitaxial layer 3 at an accelerating voltage of 40 to 180 (keV) and a dose of 1.0×10¹³ to 1.0×10¹⁶ (/cm²). Subsequently, the photoresist 35 is removed, and the N type diffusion layers 17 and 18 are formed by thermal diffusion. Note that an impurity concentration of the N type diffusion layers 17 and 18 is controlled so as to cause a junction breakdown voltage of PN junction regions 22 and 23 (see FIG. 1) to be lower than that of PN junction region 21 (see FIG. 1).

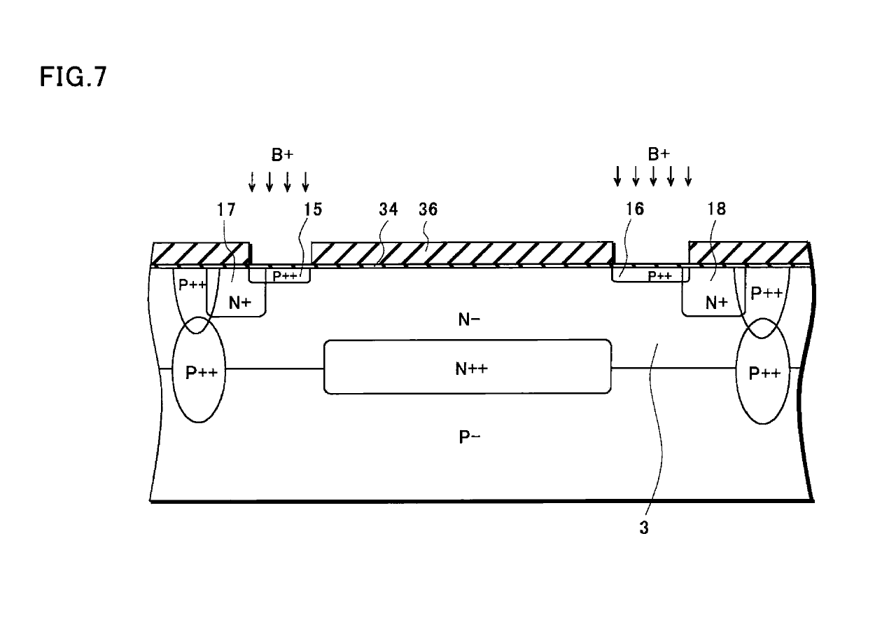

Next, as shown in FIG. 7, a photoresist 36 is formed on the silicon oxide film 34. Thereafter, by use of the heretofore known photolithography technique, openings are formed in the photoresist 36 on regions where P type diffusion layers 15 and 16 are to be respectively formed. Subsequently, ions of a P type impurity, for example, boron (B) are implanted from the surface of the epitaxial layer 3 at an accelerating voltage of 30 to 200 (keV) and a dose of 1.0×10¹⁶ to 1.0×10¹⁸ (/cm²). After the photoresist 36 is removed and the P type diffusion layers 15 and 16 are formed by thermal diffusion, the silicon oxide film 34 is removed. Note that an impurity concentration of the P type diffusion layers 15 and 16 is controlled so as to cause the junction breakdown voltage of the PN junction regions 22 and 23 (see FIG. 1) to be lower than that of the PN junction region 21 (see FIG. 1).

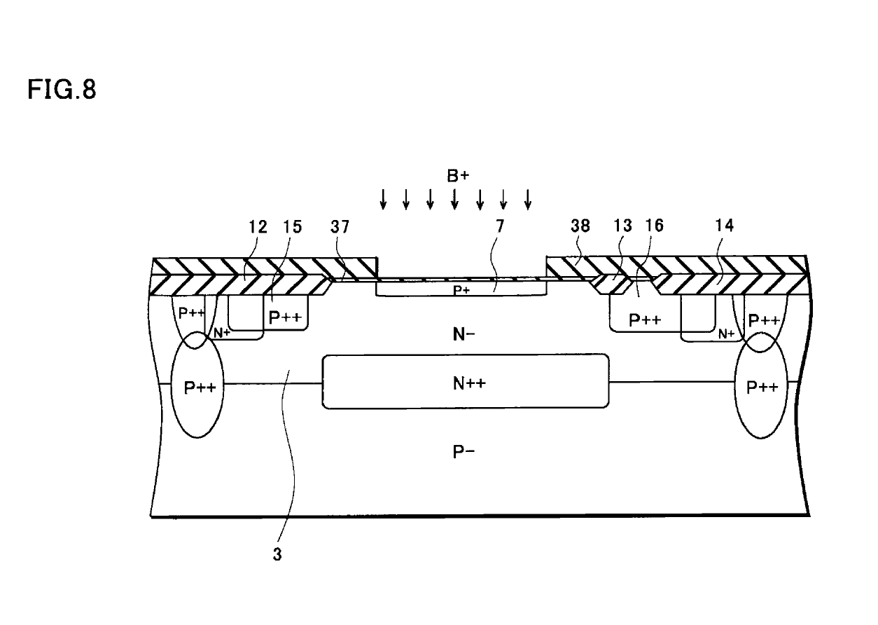

Next, as shown in FIG. 8, LOCOS oxide films 12 to 14 are formed in desired regions of the epitaxial layer 3. Thereafter, a silicon oxide film 37 is formed on the epitaxial layer 3, and a photoresist 38 is formed on the silicon oxide film 37. By use of the heretofore known photolithographic technique, an opening is formed in the photoresist 38 on a region where a P type diffusion layer 7 is to be formed. Subsequently, ions of a P type impurity, for example, boron (B) are implanted from the surface of the epitaxial layer 3 at an accelerating voltage of 40 to 180 (keV) and a dose of 1.0×10¹³ to 1.0×10¹⁵ (/cm²). Thereafter, the photoresist 38 is removed, and the P type diffusion layer 7 is formed by thermal diffusion.

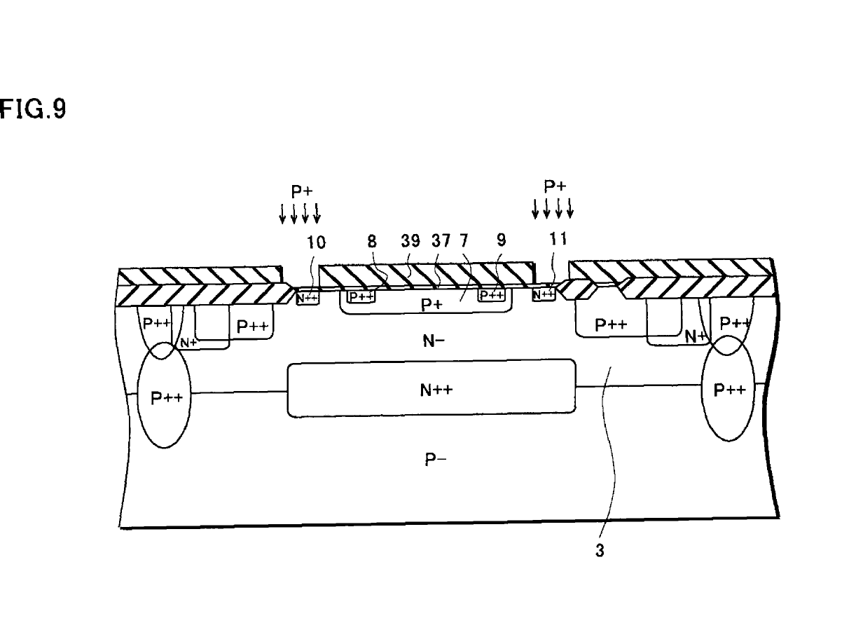

Next, as shown in FIG. 9, by use of the heretofore known photolithographic technique, P type diffusion layers 8 and 9 are formed in the epitaxial layer 3. Thereafter, a photoresist 39 is formed on the silicon oxide film 37. By use of the heretofore known photolithographic technique, openings are formed in the photoresist 39 on regions where N type diffusion layers 10 and 11 are to be formed. Subsequently, ions of an N type impurity, for example, phosphorus (P) are implanted from the surface of the epitaxial layer 3 at an accelerating voltage of 70 to 190 (keV) and a dose of 1.0×10¹⁴ to 1.0×10¹⁶ (/cm²). Thereafter, the photoresist 39 is removed, the N type diffusion layers 10 and 11 are formed by thermal diffusion, and the silicon oxide film 37 is removed.

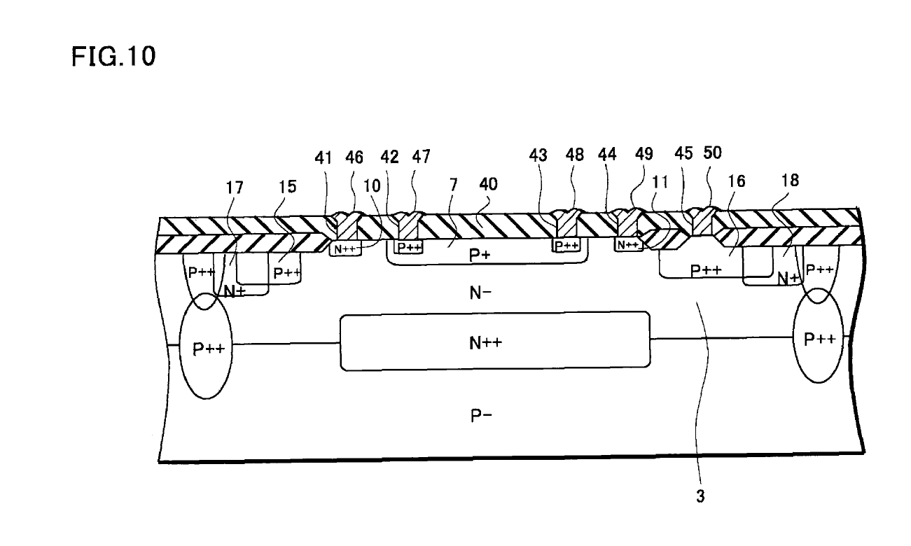

Next, as shown in FIG. 10, as an insulating layer 40, for example, a BPSG (Boron Phospho Silicate Glass) film, a SOG (Spin On Glass) film or the like is deposited on the epitaxial layer 3. Thereafter, by use of the heretofore known photolithography technique, contact holes 41 to 45 are formed in the insulating layer 40 by dry etching using, for example, CHF₃ or CF₄ gas. In the contact holes 41 to 45, aluminum alloy films made of, for example, an Al—Si film, an Al—Si—Cu film, an Al—Cu film and the like are selectively formed. Thereby, electrodes 46 to 50 are formed.

Note that, in this embodiment, description was given of the case where the P type diffusion layer 7 and the P type diffusion layers 15 and 16 are formed in separate steps. However, the embodiment of the present invention is not limited to this case. For example, the P type diffusion layers 7, 15 and 16 may be formed in the same process. In this case, the P type diffusion layers 7, 15 and 16 are diffusion layers formed under the same conditions, and have substantially the same impurity concentration. As a result, by controlling conditions for forming the N type diffusion layers 17 and 18, for example, the impurity concentration thereof, the junction breakdown voltage of the PN junction regions 22 and 23 is caused to be lower than that of the PN junction region 21. In other words, the junction breakdown voltage is determined by the conditions for forming the N type diffusion layers 17 and 18. Accordingly, control of the junction breakdown voltage is facilitated. Besides the above, various modifications can be made without departing from the scope of the embodiment of the present invention.

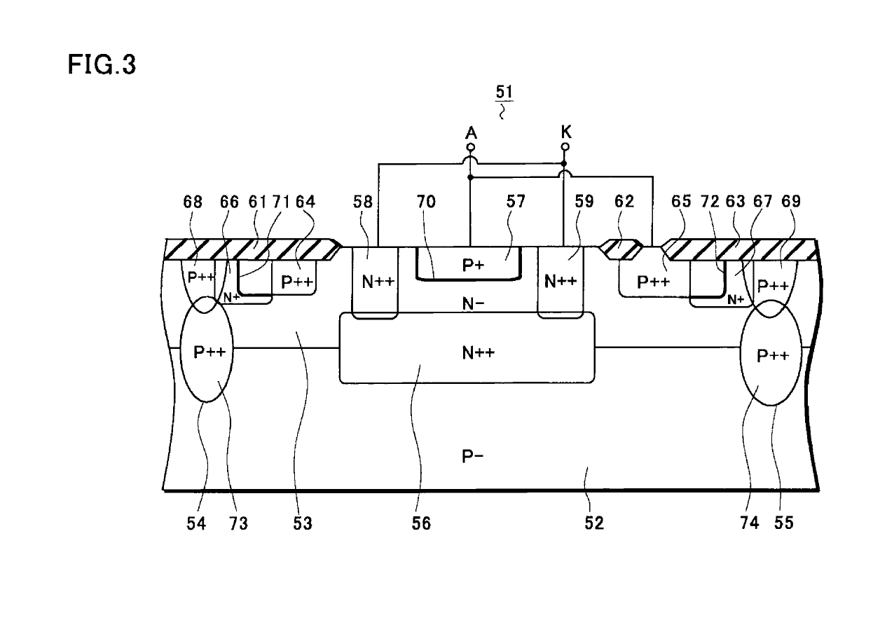

Next, with reference to FIG. 3, a semiconductor device according to a second embodiment of the present invention will be described in detail. FIG. 3 is a cross-sectional view for explaining the semiconductor device according to this embodiment.

As shown in FIG. 3, a diode 51 mainly includes a P type single crystal silicon substrate 52, an N type epitaxial layer 53, isolation regions 54 and 55, an N type buried diffusion layer 56 used as a cathode region, a P type diffusion layer 57 used as an anode region and N type diffusion layers 58 and 59 used as the cathode regions.

The N type epitaxial layer 53 is formed on the P type single crystal silicon substrate 52. Note that, although one epitaxial layer 53 is formed on the substrate 52 in this embodiment, the embodiment of the present invention is not limited to this case. For example, the substrate is stacked with a plurality of epitaxial layers.

Each of the isolation regions 54 and 55 is formed so as to extend in the substrate 52 and the epitaxial layer 53. The epitaxial layer 53 is divided into a plurality of element formation regions by the isolation regions 54 and 55. For example, the isolation regions 54 and 55 are circularly formed so as to surround a formation region of the diode 51.

The N type buried diffusion layer 56 is formed so as to extend in both regions of the substrate 52 and the epitaxial layer 53. As shown in FIG. 3, the N type buried diffusion layer 56 is formed across the formation region of the diode 51 defined by the isolation regions 54 and 55. Moreover, the N type buried diffusion layer 56 is used as the cathode region.

The P type diffusion layer 57 is formed in the epitaxial layer 53. The P type diffusion layer 57 is used as the anode region.

The N type diffusion layers 58 and 59 are formed in the epitaxial layer 53. The N type diffusion layers 58 and 59 are connected to the N type buried diffusion layer 56. The N type diffusion layers 58 and 59 are used as the cathode region. Moreover, the N type epitaxial layer 53 surrounded by the N type buried diffusion layer 56 and the N type diffusion layers 58 and 59 is used as the cathode region.

LOCOS (Local Oxidation of Silicon) oxide films 61 to 63 are formed in the epitaxial layer 53. Each of the LOCOS oxide films 61 to 63 has a thickness of, for example, about 3000 to 10000 Å in its flat portion.

P type diffusion layers 64 and 65 are formed in the epitaxial layer 53. The P type diffusion layers 64 and 65 are disposed around the formation region of the diode 51 in the region defined by the isolation regions 54 and 55. Moreover, as shown in FIG. 3, the P type diffusion layers 64 and 65 are wired so as to have the same potential as an anode potential of the diode 51. Note that the P type diffusion layers 64 and 65 may be circularly disposed around the formation region of the diode 51, and along an arrangement of the isolation regions 54 and 55.

N type diffusion layers 66 and 67 are formed in the epitaxial layer 53. The N type diffusion layers 66 and 67 are formed so as to at least partially overlap the P type diffusion layers 64 and 65, respectively. Furthermore, the N type diffusion layers 66 and 67 are formed so as to at least partially overlap P type diffusion layers 68 and 69 included in the isolation regions 54 and 55, respectively. Moreover, although the N type diffusion layers 66 and 67 are not connected directly to a wiring layer (not shown) on the epitaxial layer 53, a back gate potential is substantially applied thereto through the epitaxial layer 53. Note that the N type diffusion layers 66 and 67 may be circularly disposed around the formation region of the diode 51, and along the arrangement of the isolation regions 54 and 55.

Next, as indicated by a thick solid line, a PN junction region 70 is formed between the P type diffusion layer 57 used as the anode region of the diode 51 and the N type epitaxial layer 53 used as the cathode region. As described above, an anode potential is applied to the P type diffusion layer 57. Meanwhile, a cathode potential is applied to the N type epitaxial layer 53 through the N type diffusion layers 58 and 59. That is, a forward voltage (bias) is applied to the PN junction region 70 of the diode 51.

Moreover, as indicated by thick solid lines, a PN junction region 71 is formed between the P type diffusion layer 64 and the N type diffusion layer 66 around the formation region of the diode 51. A PN junction region 72 is also formed between the P type diffusion layer 65 and the N type diffusion layer 67 around the formation region of the diode 51. As described above, the same potential as the anode potential is applied to the P type diffusion layers 64 and 65 through the wiring layer on the epitaxial layer 53. Meanwhile, the cathode potential is substantially applied to the N type diffusion layers 66 and 67 through the epitaxial layer 53. That is, substantially the same forward voltage (bias) as that applied to the PN junction region 70 is applied to the PN junction regions 71 and 72.

Here, the PN junction regions 71 and 72 are formed so as to have a junction breakdown voltage lower than that of the PN junction region 70. For example, as shown in FIG. 3, there is a structure in which the P type diffusion layer 57 is formed in a process different from that in which the P type diffusion layers 64 and 65 are formed. Moreover, the N type diffusion layers 66 and 67 are formed in the N type epitaxial layer 53. Accordingly, in each of the PN junction regions 71 and 72, an impurity concentration in its N type region is increased, compared with the PN junction region 70. That is, by controlling the impurity concentration of the N type diffusion layers 66 and 67, the junction breakdown voltage of the PN junction regions 71 and 72 is controlled so as to have a desired characteristic value.

Moreover, although not shown in FIG. 3, there is a structure in which the P type diffusion layers 57, 64 and 65 are formed in the same process so as to have the same impurity concentration. In this case, formation of the N type diffusion layers 66 and 67 in the N type epitaxial layer 53 increases the impurity concentration on the N type region side in the PN junction regions 71 and 72 compared with the PN junction region 70. That is, by controlling the impurity concentration of the N type diffusion layers 66 and 67, the junction breakdown voltage of the PN junction regions 71 and 72 is controlled so as to have the desired characteristic value.

By use of the structure described above, for example, when an overvoltage, for example, negative ESD surge is applied to a pad for an anode electrode in the diode 51, the PN junction regions 71 and 72 break down before the PN junction region 70 break down. Accordingly, a breakdown current flows through the PN junction regions 71 and 72 to prevent breakdown of the PN junction region 70. Thereby, the diode 51 can be protected from the ESD surge. Specifically, protection elements having the PN junction regions 71 and 72 are operated against the ESD surge, and thereby the diode 51 can be protected.

Furthermore, in the protection elements having PN junction regions 71 and 72, the PN junction regions 71 and 72 are formed across wide regions by disposing the P type diffusion layers 64 and 65 and the N type diffusion layers 66 and 67, and along the arrangement of the isolation regions 54 and 55. By use of this structure, concentration of the breakdown current in the PN junction regions 71 and 72 can be prevented. Thus, it is possible to suppress breakdown of the protection elements having the PN junction regions 71 and 72.

Furthermore, the protection elements having the PN junction regions 71 and 72 are formed by utilizing the isolation regions 54 and 55 within the element formation region defined by the isolation regions 54 and 55. By use of this structure, the junction breakdown voltage of the protection element can be determined according to each of semiconductor elements formed in the element formation region defined by the isolation regions. That is, protection elements suitable for the respective semiconductor elements can be individually disposed, and thereby each of the semiconductor elements can be protected from the ESD surge and the like. For example, even when an ESD surge protection element is disposed around the pad for the anode electrode, the semiconductor elements can be more surely protected by further forming the above-described protection elements in formation regions of the respective semiconductor elements. Moreover, an actual operation region of a chip can be effectively utilized by including the protection elements in each of the element formation regions by using the isolation regions.

Next, also in the P-channel diode 51 shown in FIG. 3, each of the protection elements having the PN junction regions 71 and 72 operates as a bipolar transistor, as in the case of the N-channel resistance 1 described with reference to FIGS. 1 and 2. The P-channel diode 51 is a PNP transistor in which the P type diffusion layers 64 and 65 are emitter regions, the N type diffusion layers 66 and 67 are base regions, and the P type diffusion layers 68, 69, 73 and 74 are collector regions.

For example, considered is the case where negative ESD surge is applied to the pad for the anode electrode in the diode 51. When the PN junction regions 71 and 72 break down, a current flows between the base and the emitter of the PNP transistor, and the PNP transistor is turned on. When the PNP transistor is turned on, a breakdown current flows into the substrate 52. Specifically, when each of the protection elements having the PN junction regions 71 and 72 operates as a bipolar transistor, the breakdown current flows into the substrate 52 and disperses therein.

As described above with reference to FIGS. 1 and 2, when the breakdown current flows between the base and the emitter of the PNP transistor, the PNP transistor is turned on. In this event, when the PNP transistor is turned on, the conductivity modulation is caused at the P type diffusion layers 68, 69, 73 and 74 used as the collector regions. Accordingly, the resistance value thereof is significantly reduced, and the current capacity thereof is improved. Specifically, when each of the protection elements having the PN junction regions 71 and 72 operates as the bipolar transistor, capacity of the breakdown current flowing into the substrate 52 is improved.

Moreover, as described above with reference to FIGS. 1 and 2, when the breakdown current flows through the isolation regions 54 and 55, potentials respectively of the substrate 52 and the isolation regions 54 and 55 are changed. By operating each of the protection elements as the bipolar transistor, a range of potential changes in the substrate 52 and the isolation regions 54 and 55 can be decreased. Accordingly, malfunction of semiconductor elements formed in other element formation regions due to the potential change in the substrate 52 can be prevented.

Meanwhile, for example, when positive ESD surge is applied to the pad for the anode electrode in the diode 51, a forward bias is applied to the PN junction region 70 and the PN junction regions 71 and 72. In this case, as described above, each of the PN junction regions 71 and 72 becomes a region having low resistance by the N type diffusion layers 66 and 67. Moreover, by disposing the P type diffusion layers 64 and 65 and the N type diffusion layers 66 and 67 along the isolation regions 54 and 55, the width of a current path is increased. Accordingly, each of the PN junction regions 71 and 72 becomes a region having much lower resistance. By use of this structure, a current generated by application of the positive ESD surge flows into the substrate 52 mainly through the PN junction regions 71 and 72. Also in this event, when each of the protection elements having the PN junction regions 71 and 72 operates as the bipolar transistor, capacity of the current flowing into the substrate 52 is improved. Moreover, the diode 51 is protected by preventing breakdown of the PN junction region 70 due to concentration of the current generated by application of the positive ESD surge.

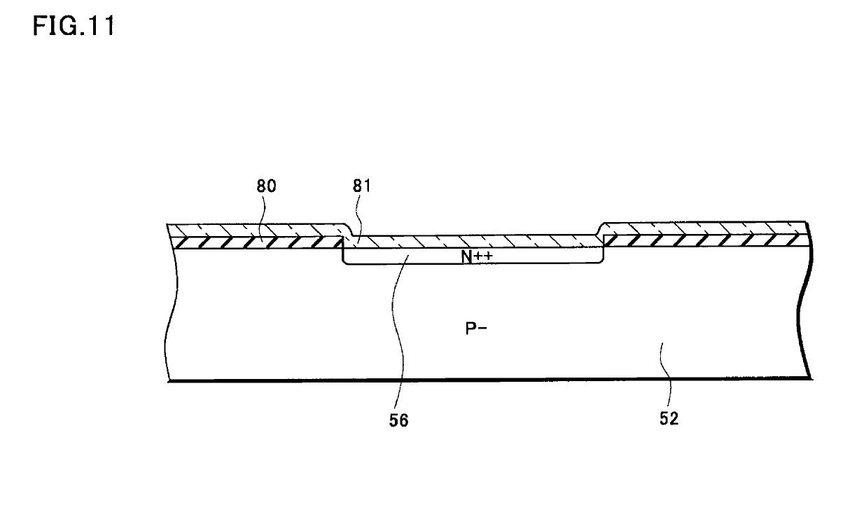

Next, with reference to FIGS. 11 to 17, detailed description will be given of a method of manufacturing a semiconductor device according to the second embodiment of the present invention. FIGS. 11 to 17 are cross-sectional views showing the method of manufacturing a semiconductor device according to this embodiment. Note that FIGS. 11 to 17 show a method of manufacturing the semiconductor device shown in FIG. 3.

First, as shown in FIG. 11, a P type single crystal silicon substrate 52 is prepared. A silicon oxide film 80 is formed on the substrate 52, and the silicon oxide film 80 is selectively removed so as to form an opening in a formation region for an N type buried diffusion layer 56. Thereafter, by using the silicon oxide film 80 as a mask, a liquid source 81 containing an N type impurity, for example, antimony (Sb) is applied onto a surface of the substrate 52 by use of a spin-coating method. Subsequently, after antimony (Sb) is thermally diffused to form the N type buried diffusion layer 56, the silicon oxide film 80 and the liquid source 81 are removed.

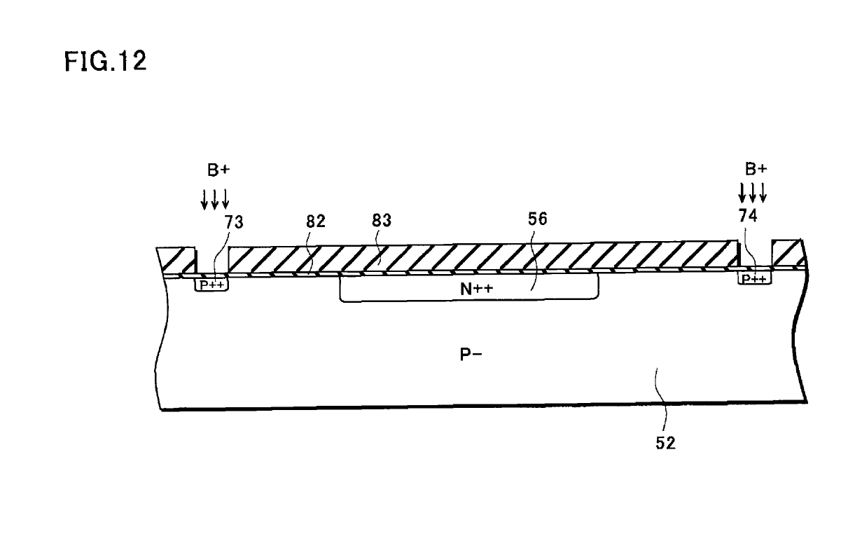

Next, as shown in FIG. 12, a silicon oxide film 82 is formed on the substrate 52 and a photoresist 83 is formed on the silicon oxide film 82. Thereafter, by use of a heretofore known photolithography technique, openings are formed in the photoresist 83 on regions where P type buried diffusion layers 73 and 74 are to be respectively formed. Subsequently, ions of a P type impurity, for example, boron (B) are implanted from the surface of the substrate 52 at an accelerating voltage of 40 to 180 (keV) and a dose of 1.0×10¹³ to 1.0×10¹⁶ (/cm²). After the photoresist 83 is removed and the P type buried diffusion layers 73 and 74 are formed by thermal diffusion, the silicon oxide film 82 is removed.

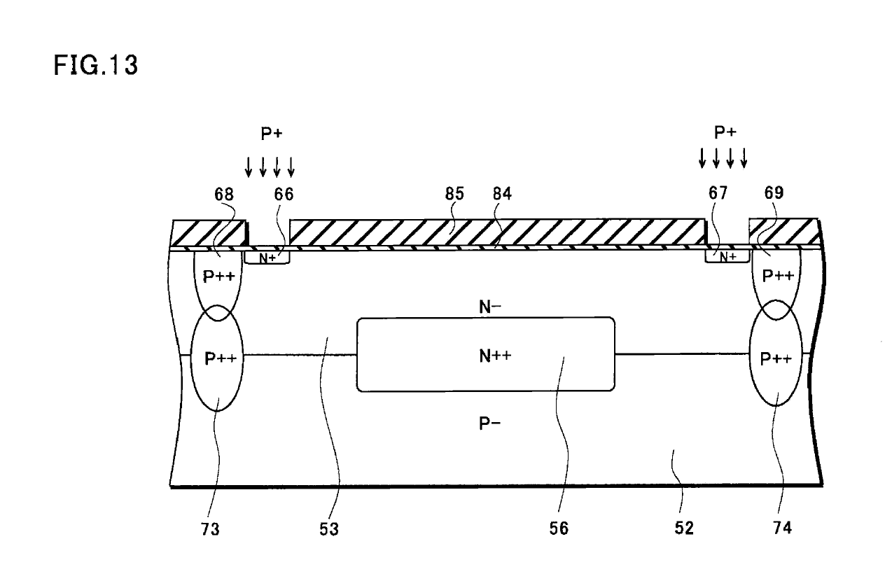

Next, as shown in FIG. 13, the substrate 52 is placed on a susceptor of a vapor phase epitaxial growth apparatus, and an N type epitaxial layer 53 is formed on the substrate 52. The vapor phase epitaxial growth apparatus mainly includes a gas supply system, a reactor, an exhaust system and a control system. In this embodiment, by use of a vertical reactor, thickness uniformity of the epitaxial layer can be improved. The N type buried diffusion layer 56 and the P type buried diffusion layers 73 and 74 are thermally diffused by heat treatment in the step of forming the epitaxial layer 53.

Next, by use of the heretofore known photolithography technique, P type diffusion layers 68 and 69 are formed in the epitaxial layer 53. Thereafter, a silicon oxide film 84 is formed on the epitaxial layer 53, and a photoresist 85 is formed on the silicon oxide film 84. Subsequently, by use of the heretofore known photolithography technique, openings are formed in the photoresist 85 on regions where N type diffusion layers 66 and 67 are to be respectively formed. Thereafter, ions of an N type impurity, for example, phosphorus (P) are implanted from the surface of the epitaxial layer 53 at an accelerating voltage of 40 to 180 (keV) and a dose of 1.0×10¹³ to 1.0×10¹⁶ (/cm²). Subsequently, the photoresist 85 is removed, and the N type diffusion layers 66 and 67 are formed by thermal diffusion. Note that an impurity concentration of the N type diffusion layers 66 and 67 is controlled so as to cause a junction breakdown voltage of PN junction regions 71 and 72 (see FIG. 3) to be lower than that of PN junction region 70 (see FIG. 3).

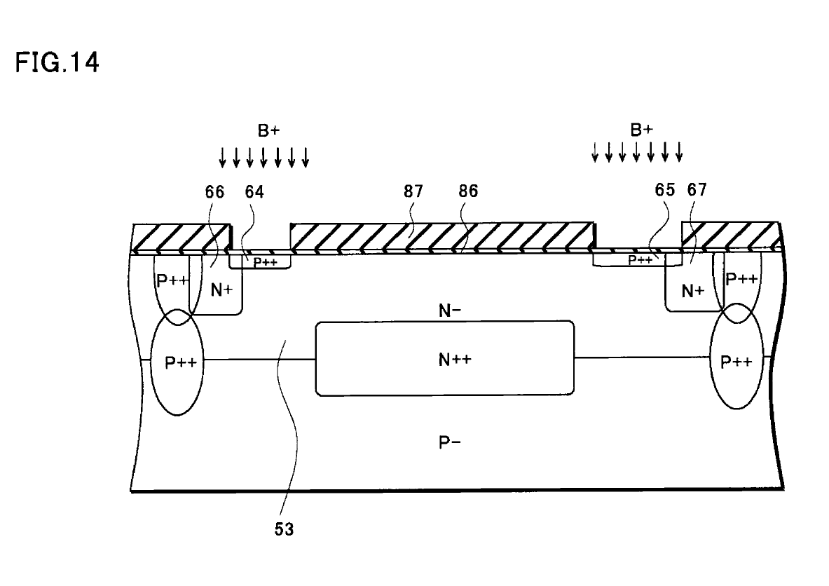

Next, as shown in FIG. 14, a photoresist 87 is formed on the silicon oxide film 86. Thereafter, by use of the heretofore known photolithography technique, openings are formed in the photoresist 87 on regions where P type diffusion layers 64 and 65 are to be respectively formed. Subsequently, ions of the P type impurity, for example, boron (B) are implanted from the surface of the epitaxial layer 53 at an accelerating voltage of 30 to 200 (keV) and a dose of 1.0×10¹⁶ to 1.0×10¹⁸ (/cm²). After the photoresist 87 is removed and the P type diffusion layers 64 and 65 are formed by thermal diffusion, the silicon oxide film 86 is removed. Note that an impurity concentration of the P type diffusion layers 64 and 65 is controlled so as to cause the junction breakdown voltage of the PN junction regions 71 and 72 (see FIG. 3) to be lower than that of the PN junction region 70 (see FIG. 3).

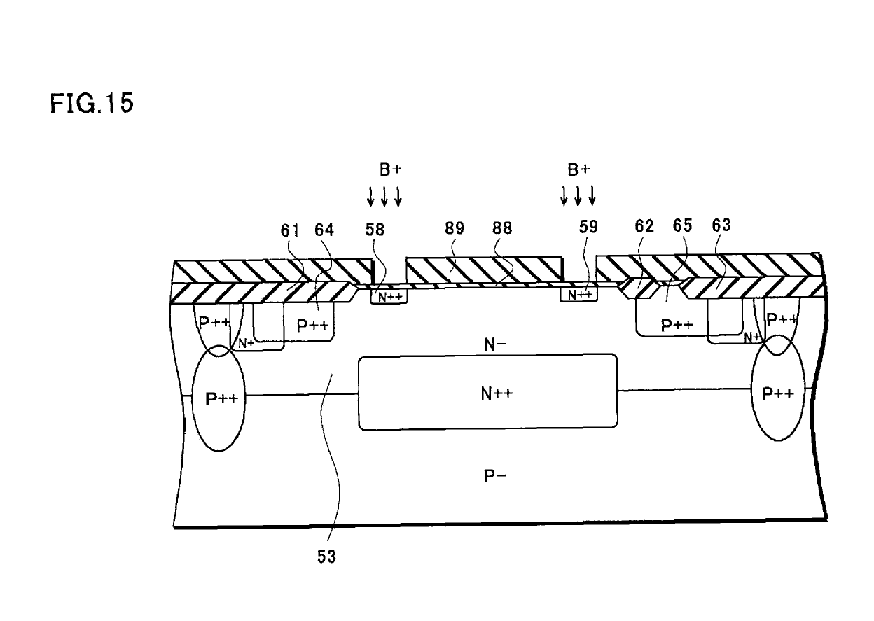

Next, as shown in FIG. 15, LOCOS oxide films 61 to 63 are formed in desired regions of the epitaxial layer 53. Thereafter, a silicon oxide film 88 is formed on the epitaxial layer 53, and a photoresist 89 is formed on the silicon oxide film 88. By use of the heretofore known photolithographic technique, openings are formed in the photoresist 89 on regions where N type diffusion layers 58 and 59 are to be formed. Subsequently, ions of an N type impurity, for example, phosphorus (P) are implanted from the surface of the epitaxial layer 53 at an accelerating voltage of 70 to 190 (keV) and a dose of 1.0×10¹⁴ to 1.0×10¹⁶ (/cm²). Thereafter, the photoresist 89 is removed, and the N type diffusion layers 58 and 59 are formed by thermal diffusion.

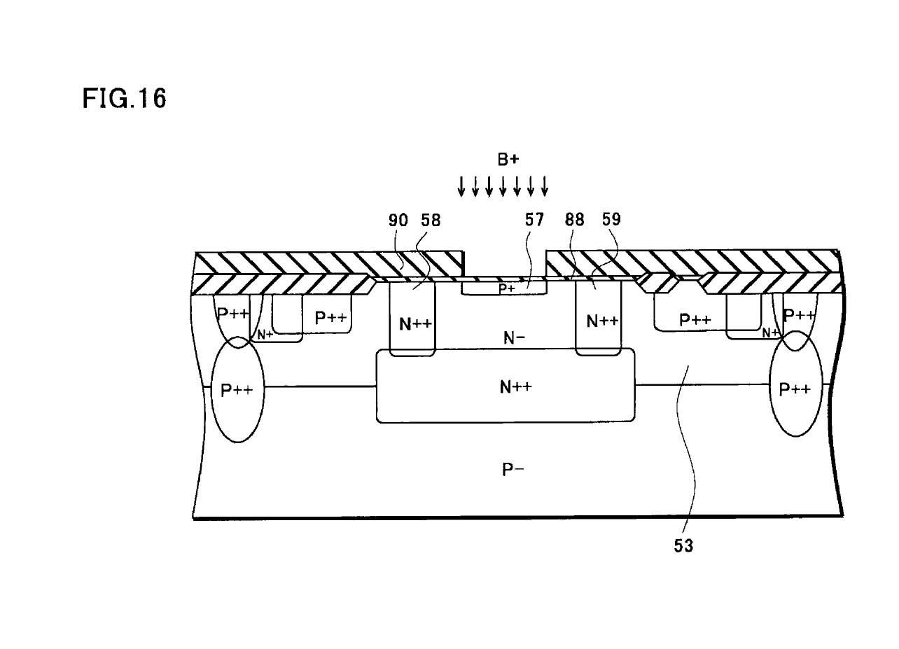

Next, as shown in FIG. 16, a photoresist 90 is formed on the silicon oxide film 88. Thereafter, by use of the heretofore known photolithographic technique, an opening is formed in the photoresist 90 on a region where a P type diffusion layer 57 is to be formed. Subsequently, ions of a P type impurity, for example, boron (B) are implanted from the surface of the epitaxial layer 53 at an accelerating voltage of 40 to 180 (keV) and a dose of 1.0×10¹⁴ to 1.0×10¹⁶ (/cm²). Thereafter, the photoresist 90 is removed, and the P type diffusion layer 57 is formed by thermal diffusion.

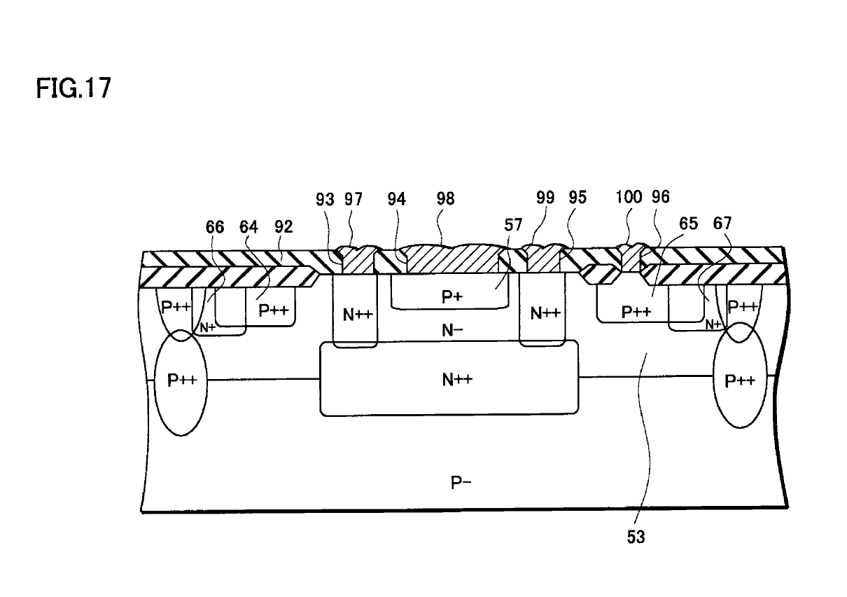

Next, as shown in FIG. 17, as an insulating layer 92, for example, a BPSG (Boron Phospho Silicate Glass) film, a SOG (Spin On Glass) film or the like is deposited on the epitaxial layer 53. Thereafter, by use of the heretofore known photolithographic technique, contact holes 93 to 96 are formed in the insulating layer 92 by dry etching using, for example, CHF₃ or CF₄ gas. In the contact holes 93 to 96, aluminum alloy films made of, for example, an Al—Si film, an Al—Si—Cu film, an Al—Cu film and the like are selectively formed. Thereby, cathode electrodes 97 and 99, an anode electrode 98, and an electrode 100 which applies a potential to the P type diffusion layer 65 are formed.

Note that, in this embodiment, description has been given of the case where the P type diffusion layers 64 and 65 and the P type diffusion layer 57 are formed in different steps from one another. However, the embodiment of the present invention is not limited to this case. For example, the P type diffusion layers 57, 64 and 65 may be formed in the same process. In this case, the P type diffusion layers 57, 64 and 65 are diffusion layers formed under the same conditions and to have substantially the same impurity concentration. As a result, by controlling conditions for forming the N type diffusion layers 66 and 67, for example, the impurity concentration thereof, the junction breakdown voltage of the PN junction regions 71 and 72 is caused to be lower than that of the PN junction region 70. In other words, the junction breakdown voltage is determined by the conditions for forming the N type diffusion layers 66 and 67. Accordingly, control of the junction breakdown voltage is facilitated. Besides the above, various modifications can be made without departing from the scope of the embodiment of the present invention.

In the embodiment of the present invention, around the resistance, the diode or the like, the protection element having the junction region which breaks down before the junction region of the resistance, the diode or the like is formed. This structure can protect the resistance, the diode or the like from the overvoltage.

Moreover, in the embodiment of the present invention, the protection element formed around the resistance, the diode or the like operates as a bipolar transistor. By using this structure, capability of discharging the current generated by the overvoltage is improved.

Moreover, in the embodiment of the present invention, the protection element having the junction region, which breaks down before the junction region of the resistance, the diode or the like, is connected to the substrate through the isolation region. This structure makes it possible to disperse the current, which is generated by the overvoltage, in the substrate after flowing into the substrate.

Moreover, in the embodiment of the present invention, the protection element having the junction region which breaks down before the junction region of the resistance, the diode or the like is formed by utilizing the isolation region. By use of this structure, protection elements suitable for individual semiconductor elements are formed in each of the element formation regions.

What is claimed is:

1. A semiconductor device comprising:
a semiconductor layer;
a diffusion layer used as a resistance formed in the semiconductor layer;
a first junction region between the semiconductor layer and the diffusion layer used as the resistance; and
a protection element, which is disposed around the diffusion layer used as the resistance, and which has a second junction region having a junction breakdown voltage lower than that of the first junction region.

2. The semiconductor device according to claim 1, further comprising:
an isolation region which divides the semiconductor layer into a plurality of regions,
wherein the diffusion layer used as the resistance is formed in one of the plurality of regions divided by the isolation region, and the protection element is formed by utilizing the isolation region surrounding the diffusion layer used as the resistance.

3. The semiconductor device according to claim 1, wherein the semiconductor layer is formed by stacking a semiconductor substrate of one conductivity type with at least one epitaxial layer of opposite conductivity type,
the second junction region is formed of a first diffusion layer of the one conductivity type to which a low potential applied to the diffusion layer used as the resistance is applied, and a diffusion layer of the opposite conductivity type formed in the epitaxial layer, and
the diffusion layer of the opposite conductivity type is disposed so as to overlap a second diffusion layer of the one conductivity type connected to the semiconductor substrate.

4. The semiconductor device according to claim 3, further comprising:
an isolation region which divides the epitaxial layer,
wherein the second diffusion layer of the one conductivity type is a diffusion layer included in the isolation region.

5. The semiconductor device according to claim 4, wherein the first diffusion layer of the one conductivity type and the diffusion layer of the opposite conductivity type are circularly disposed around the diffusion layer used as the resistance, and along a a formation region of the isolation region.

6. The semiconductor device according to any one of claims 1 and 3, wherein the protection element operates as a bipolar transistor.

7. A semiconductor device comprising:
a semiconductor layer;
a diode formed in the semiconductor layer;
a first junction region between the semiconductor layer and a diffusion layer included in the diode; and
a protection element, which is disposed around a formation region of the diode, and which has a second junction region having a junction breakdown voltage lower than that of the first junction region.

8. The semiconductor device according to claim 7, further comprising an isolation region which divides the semiconductor layer into a plurality of regions,
wherein the diode is formed in one of the plurality of regions divided by the isolation region, and
the protection element is formed by utilizing the isolation region surrounding the diode.

9. The semiconductor device according to claim 7, wherein
the semiconductor layer is formed by stacking a semiconductor substrate of one conductivity type with at least one epitaxial layer of opposite conductivity type,
the second junction region is formed of a first diffusion layer of the one conductivity type and a diffusion layer of the opposite conductivity type, the first diffusion layer of the one conductivity type connected by wiring to a diffusion layer used as an anode region of the diode, and the diffusion layer of the opposite conductivity type formed in the epitaxial layer, and
the diffusion layer of the opposite conductivity type is disposed so as to overlap a second diffusion layer of the one conductivity type connected to the semiconductor substrate.

10. The semiconductor device according to claim 9, further comprising:
an isolation region which divides the epitaxial layer,
wherein the second diffusion layer of the one conductivity type is a diffusion layer included in the isolation region.

11. The semiconductor device according to claim 9, wherein the first diffusion layer of the one conductivity type and the diffusion layer of the opposite conductivity type are circularly disposed around the formation region of the diode, and along a formation region of the isolation region.

12. The semiconductor device according to any one of claims 7 and 9, wherein the protection element operates as a bipolar transistor.

13. The semiconductor device according to claim 7, wherein a forward voltage is applied to the second junction region.

14. A method of manufacturing a semiconductor device, in which, on a semiconductor substrate of one conductivity type, at least one epitaxial layer of opposite conductivity type is formed, in which an isolation region dividing the epitaxial layer into a plurality of element formation regions is formed, and in which a diffusion layer used as a resistance is formed in one of the plurality of element formation regions, the method comprising the steps of:
forming a first diffusion layer of the one conductivity type around the diffusion layer used as the resistance;
forming a diffusion layer of the opposite conductivity type which partially overlaps the first diffusion layer of the one conductivity type and a second diffusion layer of the one conductivity type included in the isolation region; and
connecting the diffusion layer used as the resistance to the first diffusion layer of the one conductivity type by use of a wiring layer on the epitaxial layer.

15. The method of manufacturing a semiconductor device, according to claim 14, wherein the diffusion layer used as the resistance and the first diffusion layer of the one conductivity type are formed in the same process.

16. A method of manufacturing a semiconductor device, in which, on a semiconductor substrate of one conductivity type, at least one epitaxial layer of opposite conductivity type is formed, in which an isolation region dividing the epitaxial layer into a plurality of element formation regions, is formed, and in which a diode is formed in one of the plurality of element formation regions the method comprising the steps of:
forming a first diffusion layer of the one conductivity type around a formation region of the diode;
forming a diffusion layer of the opposite conductivity type which partially overlaps the first diffusion layer of the one conductivity type and a second diffusion layer of the one conductivity type included in the isolation region; and
connecting a diffusion layer used as an anode region of the diode to the first diffusion layer of the one conductivity type by use of a wiring layer on the epitaxial layer.

17. The method of manufacturing a semiconductor device, according to claim 16, wherein the diffusion layer used as the anode region of the diode and the first diffusion layer of the one conductivity type are formed in the same process.
